(19) United States
(12) Patent Application Publication
(10) Pub. No.: US 2016/0293902 A1
(43) Pub. Date: Oct. 6, 2016

(54) DISPLAY DEVICE AND METHOD OF MANUFACTURING A DISPLAY DEVICE

(71) Applicant: Japan Display Inc., Tokyo (JP)

(72) Inventors: Kengo KATO, Tokyo (JP); Norihisa MAEDA, Tokyo (JP); Takahiro USHIKUBO, Tokyo (JP)

(21) Appl. No.: 15/091,119

(22) Filed: Apr. 5, 2016

(30) Foreign Application Priority Data
Apr. 6, 2015 (JP) 2015-078010

(51) Int. Cl. H01L 51/56; H01L 51/50; H01L 51/52

(52) U.S. Cl. CPC H01L 51/56; H01L 51/5206; H01L 51/5221; H01L 51/5012; H01L 51/5008; H01L 51/5056; H01L 51/5088; H01L 51/5072; H01L 51/5092

(57) ABSTRACT

A display device according to an embodiment of the present invention includes an anode electrode layer, a cathode electrode layer, a light emitting layer arranged between the anode electrode layer and the cathode electrode layer, a carrier transport layer and a carrier injection layer, which are arranged at least one of between the light emitting layer and the cathode electrode layer or between the light emitting layer and the anode electrode layer and a mixed layer arranged between the carrier transport layer and the carrier injection layer. The mixed layer is formed of a mixture of a material of the carrier transport layer and a material of the carrier injection layer. The mixed layer is formed so that a percentage of the material of the carrier injection layer in the mixture gradually increases in a direction from the carrier transport layer toward the carrier injection layer.

### CROSS-REFERENCE TO RELATED APPLICATION

The present application claims priority from the Japanese Application JP2015-078010. The Japanese Application JP2015-078010 is incorporated by reference into this application.

### BACKGROUND OF THE INVENTION

1. Field of the Invention

One or more embodiments of the present invention relates to a display device and a method of manufacturing a display device.

2. Description of the Related Art

In recent years, an organic electroluminescent display device using a self-luminous element called an organic light emitting diode (OLED) (hereinafter referred to as organic electroluminescent element) is put to practical use.

In Japanese Patent Application Laid-open No. 2005-123095, it is disclosed that an organic electroluminescent element in which an anode transparent electrode, a hole injection layer, a mixed layer, a hole transport layer, a light emitting layer, an electron injection layer, and a cathode electrode layer are laminated in this order is used and that the mixed layer is formed by co-deposition using a material of the hole injection layer and a material of the hole transport layer.

### SUMMARY OF THE INVENTION

FIG. 7 is a schematic diagram for illustrating a section of the element structure, energy bands, and vapor deposition sources for manufacturing the element structure when a mixed layer is formed between a hole injection layer and a hole transport layer as in Japanese Patent Application Laid-open No. 2005-123095. As illustrated in a bottom part of FIG. 7, for the purpose of forming the mixed layer between the hole injection layer and the hole transport layer, a vapor deposition source for the hole injection layer, a co-deposition source for the hole injection layer and the hole transport layer, and a vapor deposition source for the hole transport layer are individually provided. The structure in which the hole injection layer, the mixed layer, and the hole transport layer are laminated as illustrated in a top part of FIG. 7 is formed through a step of forming the hole injection layer, a step of forming the mixed layer, and a step of forming the hole transport layer in this order using the respective vapor deposition sources. Therefore, in the related art, in order to form the mixed layer, the co-deposition source and a co-deposition chamber necessary for the co-deposition are required to be prepared, and thus, a load in the process of manufacturing the organic electroluminescent element is heavy.

A middle part of FIG. 7 is an illustration of energy bands of the layers formed as described above. A location in a lateral direction in the middle part of FIG. 7 is a location in a thickness direction in each of the layers. The energy bands correspond to the sectional view of the top part of FIG. 7, and are of the hole injection layer, the mixed layer, and the hole transport layer in this order from left. Further, a location in a vertical direction in the middle part of FIG. 7 denotes the magnitude of energy. A bottom side of a square of each of the layers denotes a valence band, and a top side of the square denotes a conduction band. As illustrated in the middle part of FIG. 7, a difference (so-called an energy barrier) exists in energy level of the valence band and in energy level of the conduction band between the hole injection layer and the mixed layer and between the mixed layer and the hole transport layer.

Incidentally, in general, light emission from an organic electroluminescent element is obtained as emission of light when excitation energy of excitons is relaxed, the excitons being generated by recombination of holes injected to the light emitting layer from the anode electrode layer via the hole injection layer, the mixed layer, and the hole transport layer and electrons injected to the light emitting layer from the cathode electrode layer when a voltage is applied to the element. However, the energy barriers described above are a factor in increasing the voltage applied for light emission from the organic electroluminescent element.

One or more embodiments of the present invention has been made in view of the problems described above, and an object of one or more embodiments of the present invention is to reduce the load in the process of manufacturing an organic electroluminescent element and to provide an organic electroluminescent element capable of being driven with a lower voltage.

According to one aspect of the present invention, a display device is provided. The display device includes an organic electroluminescent element. The organic electroluminescent element includes an anode electrode layer, a cathode electrode layer arranged so as to be opposed to the anode electrode layer, a light emitting layer arranged between the anode electrode layer and the cathode electrode layer, a carrier transport layer and a carrier injection layer, which are arranged at least one of between the light emitting layer and the cathode electrode layer or between the light emitting layer and the anode electrode layer and a mixed layer arranged between the carrier transport layer and the carrier injection layer. The mixed layer is formed of a mixture of a material of the carrier transport layer and a material of the carrier injection layer. The mixed layer is formed so that a percentage of the material of the carrier injection layer in the mixture gradually increases in a direction from the carrier transport layer toward the carrier injection layer.

In one embodiment of the present invention, the carrier transport layer includes a hole transport layer and the carrier injection layer includes a hole injection layer.

In one embodiment of the present invention, the carrier transport layer includes an electron transport layer and the carrier injection layer includes an electron injection layer.

According to another aspect of the present invention, a method of manufacturing a display device including an organic electroluminescent element is provided. The method includes forming an electrode layer of a conductive material and performing vapor deposition while moving a substrate above a vapor deposition source for a carrier injection layer and a vapor deposition source for a carrier transport layer, thereby forming the carrier injection layer, a mixed layer, and the carrier transport layer on the electrode layer.

In one embodiment of the present invention, each of the vapor deposition source for the carrier injection layer and the vapor deposition source for the carrier transport layer includes a plurality of vapor deposition sources arranged at equal intervals in a direction perpendicular to a moving direction of the substrate.

In one embodiment of the present invention, the substrate is moved at a constant speed.

### BRIEF DESCRIPTION OF THE DRAWINGS

FIG. 1 is a schematic view for illustrating an organic electroluminescent display device according to an embodiment of the present invention.

FIG. 2 is an illustration of the structure of an organic electroluminescent panel illustrated in FIG. 1.

FIG. 3 is a schematic example for illustrating the laminated structure of a section of a certain subpixel on a TFT substrate taken along the line III-III of FIG. 2.

FIG. 4 is an illustration of a step of forming a hole injection layer, a mixed layer, and a hole transport layer in FIG. 3.

FIG. 5 is a schematic diagram for illustrating a section of the element structure, a concentration distribution in the element, and energy bands with regard to the hole injection layer, the mixed layer, and the hole transport layer.

FIG. 6 is a schematic view for illustrating the laminated structure of a section of a subpixel according to a modification of the embodiment.

FIG. 7 is a schematic diagram for illustrating a section of the structure of an organic electroluminescent element according to the related art, energy bands, and vapor deposition sources for manufacturing the element structure.

### DETAILED DESCRIPTION OF THE INVENTION

Embodiments of the present invention are described below with reference to the attached drawings. Note that, the disclosure is only exemplary, and modifications made as appropriate within the gist of the present invention that can be conceived with ease by those skilled in the art are naturally within the scope of the present invention. For clearer illustration, some widths, thicknesses, shapes, and the like of respective portions are schematically illustrated in the drawings in comparison to actual ones. However, the widths, the thicknesses, the shapes, and the like are merely an example, and do not limit understanding of the present invention. Further, like elements as those described relating to the drawings already referred to are denoted by like reference symbols herein and in each of the drawings, and detailed description thereof is sometimes omitted as appropriate.

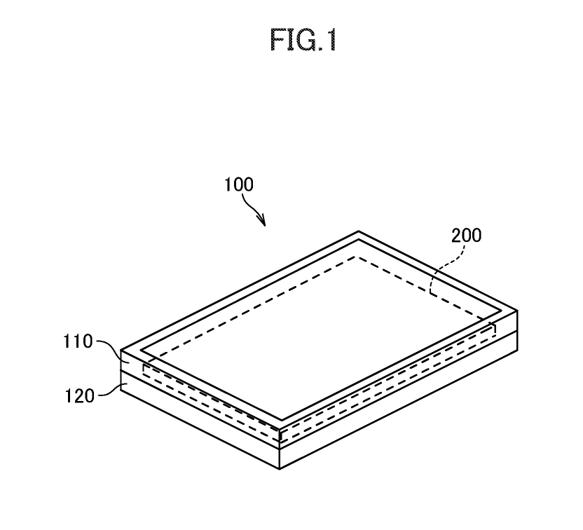

FIG. 1 is a schematic view for illustrating an organic electroluminescent display device 100 according to an embodiment of the present invention. As illustrated in FIG. 1, the organic electroluminescent display device 100 includes an organic electroluminescent panel 200 that is fixed so as to be sandwiched between an upper frame 110 and a lower frame 120.

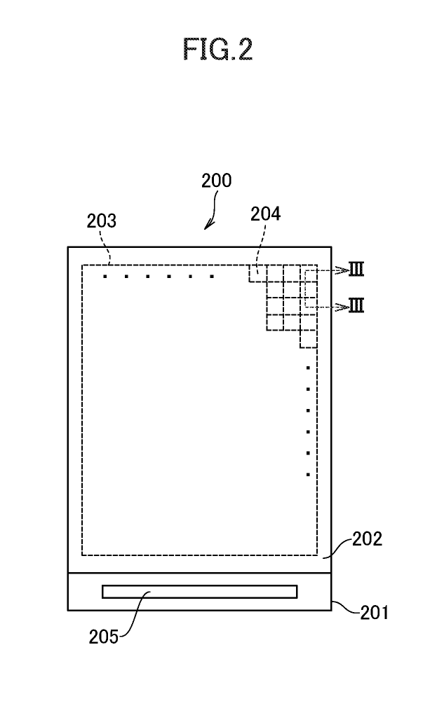

FIG. 2 is an illustration of the structure of an organic electroluminescent panel 200 illustrated in FIG. 1. The organic electroluminescent panel 200 includes two substrates. One is a thin film transistor (TFT) substrate 201, and another is a sealing substrate 202. A transparent resin is filled between the substrates.

The TFT substrate 201 includes subpixels 204 arranged in a display region 203 in a matrix-like manner. Specifically, for example, three or four subpixels 204 configured to emit light in different wavelength regions are combined together to form one pixel. The TFT substrate 201 includes a drive integrated circuit (IC) 205 for transistors arranged in the respective pixels. Specifically, for example, the drive IC 205 applies, to scanning signal lines of pixel transistors arranged in the respective subpixels 204, a potential for conduction between a source and a drain thereof, and applies, to data signal lines of the pixel transistors, voltages corresponding to grayscale values of the subpixels 204.

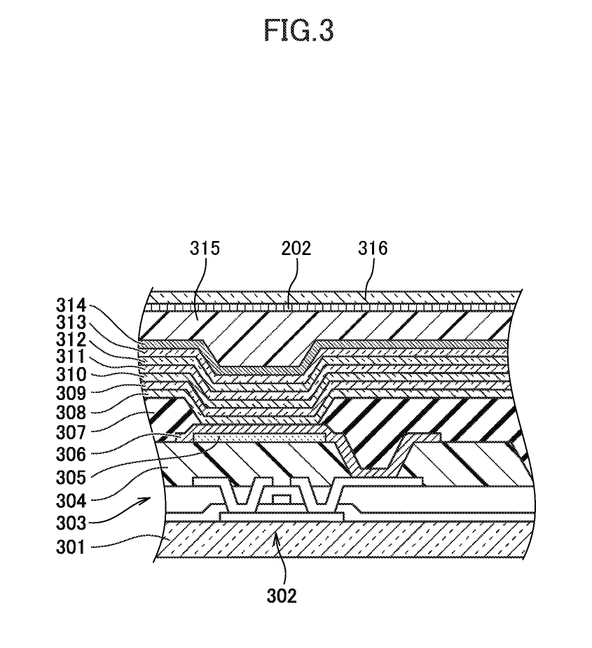

FIG. 3 is a schematic sectional view for illustrating the subpixel 204 of the organic electroluminescent panel 200 taken along the line III-III of 2. As illustrated in FIG. 3, a glass substrate 301 being an insulating substrate is arranged in the TFT substrate 201. A TFT circuit layer 303 having a circuit including a drive transistor 302 and the like formed therein, a planarizing film 304 formed of an insulating material on the TFT circuit layer 303, and a reflective layer 305 configured to reflect light emitted from a light emitting layer 311 to be described below are arranged on the glass substrate 301 in this order from bottom to top of FIG. 3. An anode electrode layer 306 connected to a circuit in the TFT circuit layer 303 via a through hole formed in the planarizing film 304, an insulating layer 307 configured to cover an end portion of the anode electrode layer 306 to insulate an electrode of a subpixel 204 from an electrode of another subpixel 204, and, a hole injection layer 308, a mixed layer 309, a hole transport layer 310, the light emitting layer 311, an electron transport layer 312, an electron injection layer 313, and a cathode electrode layer 314 that are formed on the anode electrode layer 306 and the insulating layer 307 so as to cover the entire display region 203 are arranged on the reflective layer 305. Further, a sealing film 315 configured to block entrance of air or water from the outside for preventing deterioration of the layers from the anode electrode layer 306 to the cathode electrode layer 314, a color filter layer 316 configured to transmit light of a wavelength corresponding to the color of each of the subpixels 204, and the sealing substrate 202 configured to protect the layers from the TFT circuit layer 303 to the sealing film 315 are arranged on the cathode electrode layer 314. The brightness of light emitted from the light emitting layer 311 in each of the subpixels 204 is controlled by the drive transistor 302.

In this embodiment, the structure from the anode electrode layer 306 to the cathode electrode layer 314 is referred to as an organic electroluminescent element. Further, in the embodiment illustrated in FIG. 3, the organic electroluminescent display device 100 is of a top emission type, but this is only exemplary, and the organic electroluminescent display device 100 may be of a bottom emission type, or the TFT substrate 201 used can have other structure in section. Further, as the transistor, a transistor formed of a semiconductor material such as amorphous silicon or low temperature polysilicon can be used. Further, in this embodiment, the organic layer is formed so as to cover the entire display region 203, but the organic layer may be individually formed for each of the subpixels 204. In this case, the colors of light emitted in the respective subpixels 204 can be different from one another.

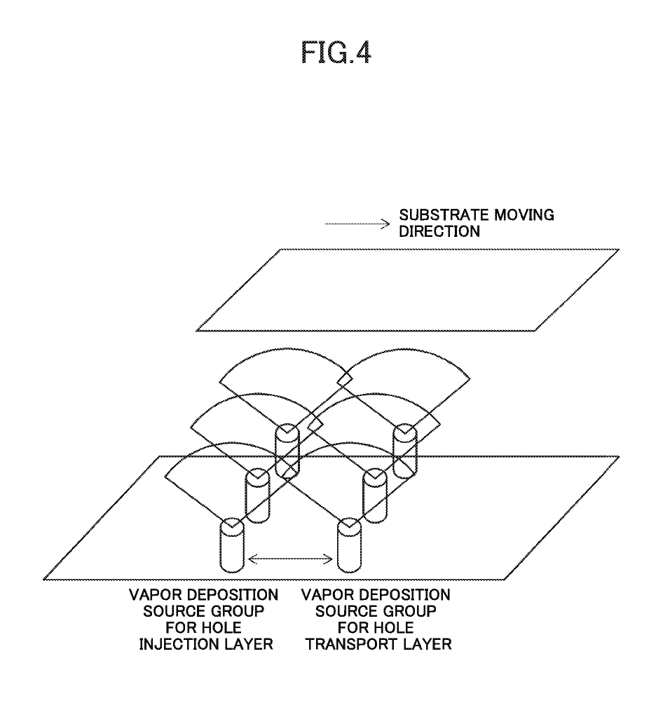

Next, a method of forming the hole injection layer 308, the mixed layer 309, and the hole transport layer 310 described with reference to FIG. 3 is described. FIG. 4 is an illustration of a step of forming the hole injection layer 308, the mixed layer 309, and the hole transport layer 310 in the process of manufacturing the organic electroluminescent display device 100 according to a first embodiment of the present invention. Note that, before the step, a step of forming layers from the TFT circuit layer 303 to the anode electrode layer 306 is performed, and, after the step, a step of forming layers from the light emitting layer 311 to the sealing film 315 is performed, but those steps are similar to related-art ones, and thus, description thereof is omitted here.

As illustrated in FIG. 4, both a plurality of vapor deposition sources for the hole injection layer 308 and a plurality of vapor deposition sources for the hole transport layer 310 are arranged at equal intervals in a direction perpendicular to a moving direction of the substrate. The substrate is in a state in which layers up to the anode electrode layer 306 illustrated in FIG. 3 are already formed thereon, and is arranged on a left side of a region in which the vapor deposition sources for the hole injection layer 308 are arranged. Both the vapor deposition sources for the hole injection layer 308 and the vapor deposition sources for the hole transport layer 310 are in a state of being able to heat and vaporize a vapor deposition material and to perform vapor deposition at a film forming rate that is set in advance.

First, the substrate arranged on the left side in FIG. 4 starts to move to a right side. When the substrate reaches a region in which vaporized, molecules from the vapor deposition sources for the hole injection layer 308 are adsorbed (fan-shaped regions illustrated in FIG. 4 above the vapor deposition source group for the hole injection layer 308), the hole injection layer 308 is formed on the substrate. In this state, the substrate has not yet reached a region in which vaporized molecules from the vapor deposition sources for the hole transport layer 310 are adsorbed (fan-shaped regions illustrated in FIG. 4 above the vapor deposition source group for the hole transport layer 310), and thus, the hole injection layer 308 that does not contain a material of the hole transport layer 310 is formed on the substrate.

When the substrate continues to move to the right side, the substrate reaches a region in which the region in which vaporized molecules from the vapor deposition sources for the hole injection layer 308 are adsorbed and the region in which vaporized molecules from the vapor deposition sources for the hole transport layer 310 are adsorbed overlap. Both a material of the hole injection layer 308 and the material of the hole transport layer 310 exist in a vaporized state in the region, and thus, the mixed layer 309 of the hole injection layer 308 and the hole transport layer 310 is formed on the substrate. Note that, the ratio between the material of the hole injection layer 308 and the material of the hole transport layer 310 contained in the mixed layer 309 is described below.

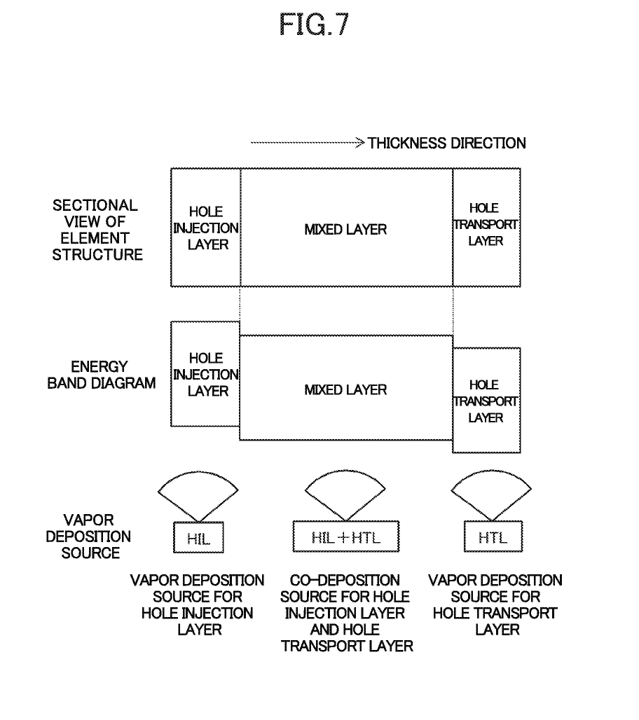

When the substrate further continues to move to the right side, the substrate passes the region in which vaporized molecules from the vapor deposition sources for the hole injection layer 308 are adsorbed to reach the region in which only vaporized molecules from the vapor deposition sources for the hole transport layer 310 are adsorbed. Only the material of the hole transport layer 310 exists in a vaporized state in the region, and thus, the hole transport layer 310 that does not contain the material of the hole injection layer 308 is formed on the substrate. As described above, through passing of the substrate above the vapor deposition sources for the hole injection layer 308 and the vapor deposition sources for the hole transport layer 310 in this order, the hole injection layer 308, the mixed layer 309, and the hole transport layer 310 are formed in one step. Therefore, compared with a case of the related art as described with reference to FIG. 7, according to this embodiment, a load in the process of manufacturing the organic electroluminescent element can be reduced.

It is desired that the substrate be moved at a constant speed. A constant speed of moving the substrate enables smooth changes in the percentages of the material of the hole injection layer 308 and of the material of the hole transport layer 310 in the mixed layer 309 to be described below.

Further, each of the vapor deposition source group for the hole injection layer 308 and the vapor deposition source group for the hole transport layer 310 includes a plurality of vapor deposition sources arranged in a line at equal intervals in the direction perpendicular to the moving direction of the substrate, but the layout of the arrangement of the vapor deposition sources is not limited thereto. Specifically, for example, any one or both of the vapor deposition source group for the hole injection layer 308 and the vapor deposition source group for the hole transport layer 310 may include vapor deposition sources arranged in a plurality of lines in the direction perpendicular to the moving direction of the substrate, or may include vapor deposition sources arranged in a staggered line. Specifically, the vapor deposition sources for the hole injection layer 308 and the vapor deposition sources for the hole transport layer 310 may be arranged so that the thicknesses of the hole injection layer 308 and the hole transport layer 310 are uniform in the direction perpendicular to the moving direction of the substrate.

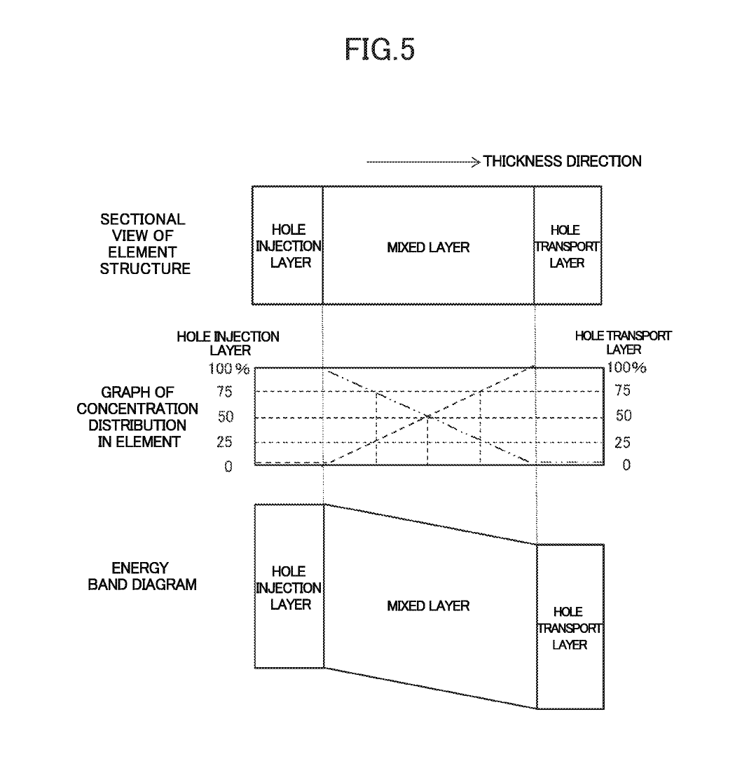

Next, a section of the element structure, a concentration distribution in the element, and energy bands with regard to the hole injection layer 308, the mixed layer 309, and the hole transport layer 310 formed in the method described with reference to FIG. 4 are described with reference to FIG. 5. A top part of FIG. 5 is a sectional view of the element formed in the method described with reference to FIG. 4, and is an illustration of the hole injection layer 308, the mixed layer 309, and the hole transport layer 310 that are laminated in this order to the right side in FIG. 5 (in a thickness direction of the element).

A middle part of FIG. 5 is a graph for showing percentages in concentration of the material of the hole injection layer 308 and of the material of the hole transport layer 310 in the element with regard to the respective layers, and corresponds to the sectional view of the top part of FIG. 5. As shown in the middle part of FIG. 5, in the ratio in concentration between the material of the hole injection layer 308 and the material of the hole transport layer 310 in the hole injection layer 308, the percentage of the material of the hole injection layer 308 and the percentage of the material of the hole transport layer 310 are 100% and 0%, respectively. The hole injection layer 308 is formed in a state in which the substrate has already reached the region in which vaporized molecules from the vapor deposition sources for the hole injection layer 308 are adsorbed but has not yet reached the region in which vaporized molecules from the vapor deposition sources for the hole transport layer 310 are adsorbed.

The percentage of the material of the hole injection layer 308 in the mixed layer 309 gradually reduces from 100% on a border between the hole injection layer 308 and the mixed layer 309 toward a border between the hole transport layer 310 and the mixed layer 309. On the other hand, the percentage of the material of the hole transport layer 310 in the mixed layer 309 gradually increases from 0% on the border between the hole injection layer 308 and the mixed layer 309 toward the border between the hole transport layer 310 and the mixed layer 309. Specifically, for example, the percentages of the material of the hole injection layer 308 and of the material of the hole transport layer 310 at a middle portion of the mixed layer 309 in the thickness direction are 50% and 50%, respectively. Specifically, the mixed layer 309 is formed in a state in which. the substrate is in the region where the region in which vaporized molecules from the vapor deposition sources for the hole injection layer 308 are adsorbed and the region in which vaporized molecules from the vapor deposition sources for the hole transport layer 310 are adsorbed overlap. The mixed layer formed in a region closer to the vapor deposition sources for the hole injection layer 308 has a higher percentage of the material of the hole injection layer 308, and the mixed layer formed in a region closer to the vapor deposition sources for the hole transport layer 310 has a higher percentage of the material of the hole transport layer 310. Note that, the graph for showing the concentration distribution in the mixed layer 309 in the middle part of FIG. 5 is a distribution graph when the substrate is moved at a constant speed.

Further, in the ratio in concentration between the material of the hole injection layer 308 and the material of the hole transport layer 310 in the hole transport layer 310, the percentage of the material of the hole injection layer 308 and the percentage of the material of the hole transport layer 310 are 0% and 100%, respectively. The hole transport layer 310 is formed in a state in which the substrate has passed the region in which vaporized molecules from the vapor deposition sources for the hole injection layer 308 are adsorbed and is in the region in which only vaporized molecules from the vapor deposition sources for the hole transport layer 310 are adsorbed.

A bottom part of FIG. 5 is an illustration of energy bands of the layers. A location in a lateral direction in the bottom part of FIG. 5 is a location in the thickness direction in each of the layers, and a location in a vertical direction therein denotes the magnitude of energy. Similarly to the case in the bottom part of FIG. 7, the energy bands correspond to the sectional view of the top part of FIG. 5, and are of the hole injection layer 308, the mixed layer 309, and the hole transport layer 310 in this order from left. A bottom side of a square of each of the layers denotes a valence band, and a top side of the square denotes a conduction band. As illustrated in the bottom part of FIG. 5, the valence band and the conduction band in the mixed layer 309 gradually change from the hole injection layer 308 side toward the hole transport layer 310 so as to be at the same levels of the valence band and the conduction band in the hole injection layer 308 and in the hole transport layer 310. Therefore, according to this embodiment, compared with the related art as illustrated in FIG. 7, the energy barriers that exist between the hole injection layer 308 and the mixed layer 309 and between the mixed layer 309 and the hole transport layer 310 are lowered, and thus, a drive voltage applied for light emission from the organic electroluminescent element can be reduced.

In the above, an embodiment in which the substrate is moved at a constant speed is described, but the speed of moving the substrate may be changed. In the middle part of FIG. 5, a case in which the percentages of the materials in the mixed layer 309 linearly change is shown, but, even through changing the speed of moving the substrate to gradually change (for example, in a curved manner) the percentages of the material of the hole injection layer 308 and of the material of the hole transport layer 310 in the mixed layer 309, an effect of reducing the drive voltage is obtained.

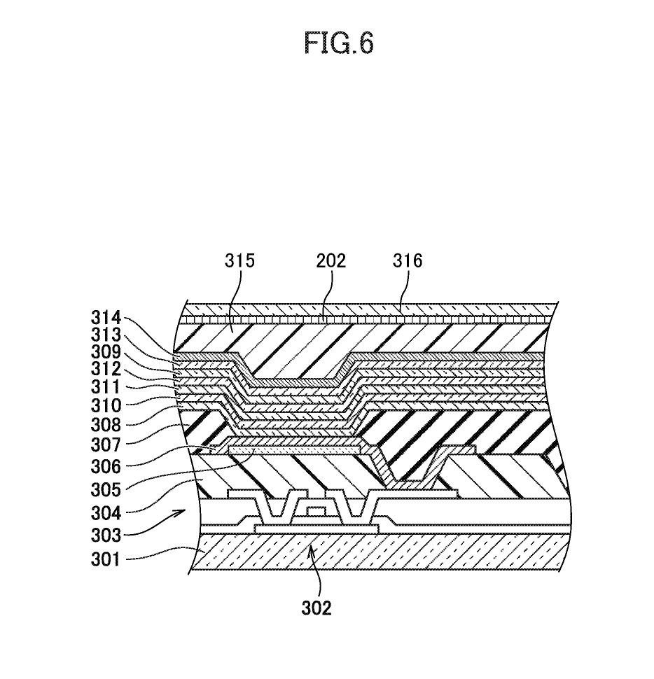

Further, in the embodiment described above, the mixed layer 309 is arranged between the hole injection layer 308 and the hole transport layer 310, but the location of the mixed layer 309 is not limited to the one described in the embodiment described above, and the mixed layer 309 may be arranged between a carrier transport layer and a carrier injection layer. A specific modification is described below with reference to FIG. 6.

FIG. 6 is a schematic view for illustrating the laminated structure of an organic electroluminescent element according to the modification of the embodiment described above. The organic electroluminescent element is different from the one illustrated in FIG. 3 in that the mixed layer 309 is arranged not between the hole transport layer 310 and the hole injection layer 308 but between the electron transport layer 312 and the electron injection layer 313, and that the material of the mixed layer 309 is formed of a mixture of a material of the electron transport layer 312 and a material of the electron injection layer 313.

Similarly to the case illustrated in FIG. 3, in the TFT substrate 201, the glass substrate 301 being an insulating substrate is arranged. Layers from the TFT circuit layer 303 to the anode electrode layer 306 that are similar to those illustrated in FIG. 3 are formed on the glass substrate 301 in this order from bottom to top of FIG. 6. The hole injection layer 308, the hole transport layer 310, the light emitting layer 311, the electron transport layer 312, the mixed layer 309, the electron injection layer 313, and the cathode electrode layer 314 that are formed on the anode electrode layer 306 and the insulating layer 307 so as to cover the entire display region 203 are arranged in this order. A method of manufacturing the electron transport layer 312, the mixed layer 309, and the electron injection layer 313 according to this modification is similar to the manufacturing method described with reference to FIG. 4 except that the vapor deposition sources for the hole injection layer 308 are changed to vapor deposition sources for the electron transport layer 312 and the vapor deposition sources for the hole transport layer 310 are changed to vapor deposition sources for the electron injection layer 313. Compared with the case of the related art, the load in the process of manufacturing the organic electroluminescent element can be reduced.

Further, even in the structure in which the mixed layer 309 is between the electron transport layer 312 and the electron injection layer 313 as in this modification, through lowering of the energy barriers when electrons are injected from the cathode electrode layer 314 into the light emitting layer 311, similarly to the case of the embodiment described above, the effect of reducing the drive voltage can be obtained. Note that, the structure may be such that the mixed layer 309 is formed both between the electron transport layer 312 and the electron injection layer 313 and between the hole injection layer 308 and the hole transport layer 310, not any one of between the electron transport layer 312 and the electron injection layer 313 and between the hole injection layer 308 and the hole transport layer 310.

Those skilled in the art can conceive various modifications and variations within the scope of the idea of the present invention, and it is understood that those modifications and variations also fall within the scope of the present invention. For example, when a structural element is added to or deleted from, or a design change is made to, or, when a step is added to or deleted from, or a condition change is made to the embodiments described above as appropriate by those skilled in the art, insofar as such modifications and variations are within the gist of the present invention, such modifications and variations fall within the scope of the present invention.

What is claimed is:

1. A display device, comprising an organic electroluminescent element, the organic electroluminescent element comprising:
an anode electrode layer;
a cathode electrode layer arranged so as to be opposed to the anode electrode layer;
a light emitting layer arranged between the anode electrode layer and the cathode electrode layer;
a carrier transport layer and a carrier injection layer, which are arranged at least one of between the light emitting layer and the cathode electrode layer or between the light emitting layer and the anode electrode layer; and
a mixed layer arranged between the carrier transport layer and the carrier injection layer,
wherein the mixed layer is formed of a mixture of a material of the carrier transport layer and a material of the carrier injection layer, and
wherein the mixed layer is formed so that a percentage of the material of the carrier injection layer in the mixture gradually increases in a direction from the carrier transport layer toward the carrier injection layer.

2. The display device according to claim 1, wherein the carrier transport layer comprises a hole transport layer and the carrier injection layer comprises a hole injection layer.

3. The display device according to claim 1, wherein the carrier transport layer comprises an electron transport layer and the carrier injection layer comprises an electron injection layer.

4. A method of manufacturing a display device including an organic electroluminescent element, the method comprising:
forming an electrode layer of a conductive material; and
performing vapor deposition while moving a substrate above a vapor deposition source for a carrier injection layer and a vapor deposition source for a carrier transport layer, thereby forming the carrier injection layer, a mixed layer, and the carrier transport layer on the electrode layer.

5. The method of manufacturing a display device according to claim 4, wherein each of the vapor deposition source for the carrier injection layer and the vapor deposition source for the carrier transport layer comprises a plurality of vapor deposition sources arranged at equal intervals in a direction perpendicular to a moving direction of the substrate.

6. The method of manufacturing a display device according to claim 4, wherein the substrate is moved at a constant speed.
